(19) United States
(12) Patent Application Publication
(10) Pub. No.: US 2025/0038150 A1
(43) Pub. Date: Jan. 30, 2025

(54) CHIP-PACKAGE STRUCTURE AND FABRICATION METHOD THEREOF, MEMORY SYSTEM AND ELECTRONIC APPARATUS

(71) Applicant: YANGTZE MEMORY TECHNOLOGIES CO., LTD., Wuhan (CN)

(72) Inventors: Xiaoxin Liu, Wuhan (CN); Zongliang Huo, Wuhan (CN)

(21) Appl. No.: 18/384,259

(22) Filed: Oct. 26, 2023

Related U.S. Application Data
(63) Continuation of application No. PCT/CN2023/109175, filed on Jul. 25, 2023.

(51) Int. Cl. H01L 25/065; G11C 16/08; H10B 41/27; H10B 41/35; H10B 41/43; H10B 43/27; H10B 43/35; H10B 43/40; H10B 80/00

(52) U.S. Cl. CPC H01L 25/0657; G11C 16/08; H10B 41/27; H10B 41/35; H10B 41/43; H10B 43/27; H10B 43/35; H10B 43/40; H10B 80/00; H01L 2225/06513

(57) ABSTRACT

According to one aspect of the present disclosure, a chip-package structure is provided. The chip-package structure may include a first chip. The first chip may include at least a peripheral circuit associated with a first transistor. The chip-package structure may include a second chip. The second chip may include at least a column decoder associated with a second transistor. The chip-package structure may include a third chip. The third chip may include at least a control circuit associated with a third transistor. The first chip, the second chip, and the third chip may form a stacked structure. A first channel length of the first transistor, a second channel length of the second transistor, and a third channel length of the third transistor may be different.

### CROSS-REFERENCE TO RELATED APPLICATIONS

This application is a continuation of International Application No. PCT/CN2023/109175, filed on Jul. 25, 2023, the content of which is incorporated herein by reference in its entirety.

### TECHNICAL FIELD

The present disclosure relates to the field of semiconductor chip technology, in particular to a chip-package structure and a fabrication method thereof, a memory system and an electronic apparatus.

### BACKGROUND

As the feature sizes of memory cells approach the processing lower limit of, planar process and manufacturing techniques have become challenging and expensive. This has resulted in the memory density for 2D or planar NAND flashes approaching an upper limit.

In order to overcome limitations on 2D or planar NAND flashes, memories with three-dimensional structure (3D NAND) have been developed in the industry, which improve the memory density by arranging memory cells on the substrate in three dimensions.

### SUMMARY

According to one aspect of the present disclosure, a chip-package structure is provided. The chip-package structure may include a first chip. The first chip may include at least a peripheral circuit associated with a first transistor. The chip-package structure may include a second chip. The second chip may include at least a column decoder associated with a second transistor. The chip-package structure may include a third chip. The third chip may include at least a control circuit associated with a third transistor. The first chip, the second chip, and the third chip may form a stacked structure. A first channel length of the first transistor, a second channel length of the second transistor, and a third channel length of the third transistor may be different.

In some implementations, the peripheral circuit may include at least a word line driver and a page buffer each including the first transistor. In some implementations, the second chip further includes a power management circuit including the second transistor. In some implementations, the third chip may further include an I/O interface circuit including the third transistor.

In some implementations, the first transistor, the second transistor and the third transistor may each be a complementary metal-oxide-semiconductor (CMOS) transistor. In some implementations, the column decoder further includes a fourth transistor and a fifth transistor. In some implementations, the fourth transistor may be a bipolar transistor and the fifth transistor may be a double-diffused metal-oxide-semiconductor (DMOS) transistor.

In some implementations, the second chip further includes a power management circuit. In some implementations, the power management circuit includes the fourth transistor and the fifth transistor.

In some implementations, the chip-package structure may further include a fourth chip. In some implementations, the fourth chip may include a volatile memory. In some implementations, the fourth chip may be stacked with the first chip, the second chip, and the third chip.

In some implementations, the chip-package structure may include a fourth chip. In some implementations, the fourth chip may include a volatile memory. In some implementations, the first chip, the second chip, and the third chip may be stacked in a first direction. In some implementations, the fourth chip may be placed adjacent to the stack structure in a second direction perpendicular to the first direction.

In some implementations, one chip of two adjacent chips in the stacked structure may include a first dielectric layer on one of its surfaces and a first conductive pattern penetrating the first dielectric layer. In some implementations, another chip of the two adjacent chips in the stacked structure may include a second dielectric layer on one of its surfaces and a second conductive pattern penetrating the second dielectric layer. In some implementations, the first conductive pattern may be bonded with the second conductive pattern. In some implementations, the first dielectric layer may be bonded with the second dielectric layer.

In some implementations, one chip of two adjacent chips in the stack structure may include a first dielectric layer on one of its surfaces and a first conductive pattern penetrating the first dielectric layer. In some implementations, another chip of the two adjacent chips in the stack structure may include a second dielectric layer on one of its surfaces and a second conductive pattern penetrating the second dielectric layer. In some implementations, the chip-package structure further may include a connection structure through which the first conductive pattern is electrically connected with the second conductive pattern.

In some implementations, the connection structure may include any one of a solder ball, a solder bump, or a copper (Cu) pillar.

In some implementations, the first chip may include a first surface close to or away from a side of the second chip. In some implementations, the connection structure may have a circular orthogonal projection on the first surface. In some implementations, a diameter of the circular orthogonal projection may be in a range of 1 um-10 um.

In some implementations, the first chip may include a first surface close to or away from a side of the second chip. In some implementations, the connection structure may include a plurality of the connection structures arranged in an array in a direction parallel to the first surface. In some implementations, a spacing between two adjacent connection structures may be in a range of 1 um-10 um.

In some implementations, the chip-structure may further include a fifth chip. In some implementations, the fifth chip may include a three-dimensional memory array. In some implementations, the fifth chip may be stacked with the first chip, the second chip and the third chip. In some implementations, the fifth chip may be disposed adjacent to the first chip.

In some implementations, the first channel length of the first transistor may be in a range of 40 nm-180 nm. In some implementations, the second channel length of the second transistor may be greater than or equal to 130 nm. In some implementations, the third channel length of the third transistor is in a range of 14 nm-40 nm.

According to another aspect of the present disclosure, a method of fabricating a chip-package structure is provided. The method may include forming a first chip. The first chip may include at least a peripheral circuit. The at least one peripheral circuit may include a first transistor. The method may include forming a second chip. The second chip may include at least a column decoder. The at least the column decoder may include a second transistor. The method may include forming a third chip. The third chip may include at least a control circuit. The third chip may include a third transistor. The method may include stacking the first chip, the second chip, and the third chip to form a stack structure. A first channel length of the first transistor, a second channel length of the second transistor, and a third channel length of the third transistor may be different.

In some implementations, the first chip, the second chip, and the third chip may each include a plurality of circuits. In some implementations, the method may further include forming the plurality of circuits on a same chip using the same process. In some implementations, the method may further include forming the plurality of circuits on different chips with different process parameters.

In some implementations, the method may further include forming a fourth chip comprising a volatile memory. In some implementations, the method may further include stacking the fourth chip with the first chip, the second chip, and the third chip.

In some implementations, surfaces of two adjacent chips in the stack structure may be connected using a bonding process.

In some implementations, two adjacent chips of the stack structure may be connected using a connection structure.

In some implementations, before the stacking the first chip, the second chip, and the third chip to form the stack structure, the method may further include connecting a surface of a fifth chip and a surface of the first chip using a bonding process to form a bonded structure. In some implementations, the first chip may include a three-dimensional memory array. In some implementations, the stacking the first chip, the second chip, and the third chip to form the stack structure may include stacking the bonded structure, the second chip, and the third chip.

According to a further aspect of the present disclosure, a memory system is provided. The memory system may include a chip-package structure. The chip-package structure may include a first chip. The first chip may include at least a peripheral circuit associated with a first transistor. The chip-package structure may include a second chip. The second chip may include at least a column decoder associated with a second transistor. The chip-package structure may include a third chip. The third chip may include at least a control circuit associated with a third transistor. The first chip, the second chip, and the third chip may form a stacked structure. A first channel length of the first transistor, a second channel length of the second transistor, and a third channel length of the third transistor may be different. The memory system may include a circuit board electrically connected with the chip-package structure.

In yet another aspect, an electronic apparatus including the memory system as described above is provided.

It is appreciated that the beneficial effects that can be achieved by the memory system and the electronic apparatus provided in the above-described implementations of the present disclosure can be inferred with reference to the beneficial effects of the chip-package structure described above, and will not be described again herein.

### BRIEF DESCRIPTION OF DRAWINGS

In order to explain the technical solutions in the present disclosure more clearly, accompanying drawings required in some implementations of the present disclosure will be described in brief below. It is obvious that the below described drawings are only drawings of some implementations of the present disclosure and other drawings may be obtained according to these drawings for those of ordinary skill in the art. Furthermore, accompanying drawings described below may be regarded as illustrative diagrams rather than limiting the practical sizes of products, practical flows of methods and practical timings of signals involved in implementations of the present disclosure.

FIG. 1 is a block diagram of an electronic apparatus, according to some implementations of the present disclosure.

FIG. 2 is a block diagram of a memory system, according to some implementations of the present disclosure.

FIG. 3 is a structure diagram of a memory system, according to some implementations of the present disclosure.

FIG. 4 is a block diagram of a first chip, according to some implementations of the present disclosure.

FIG. 5 is a block diagram of a second chip, according to some implementations of the present disclosure.

FIG. 6 is a block diagram of a third chip, according to some implementations of the present disclosure.

FIG. 7 is a structure diagram of a transistor in the chip, according to some implementations of the present disclosure.

FIGS. 8A and 8B are structure diagrams of some other memory systems, according to some implementations of the present disclosure.

FIG. 9 is a diagram of a connection between chips, according to some implementations of the present disclosure.

FIG. 10 is a sectional diagram along the section line A-A′ in the structure shown in FIG. 9, according to some implementations of the present disclosure.

FIG. 11 is a diagram of a connection between chips, according to some implementations of the present disclosure.

FIG. 12 is a flow diagram of fabricating a chip-package structure, according to some implementations of the present disclosure.

FIGS. 13A-13G are flow diagrams for a method of fabricating a chip-package structure, according to some implementations of the present disclosure.

FIG. 14 is a structure diagram of yet another memory system, according to some implementations of the present disclosure.

FIGS. 15A-15B are flow diagrams of a method of fabricating a chip-package structure, according to some implementations of the present disclosure.

### DETAILED DESCRIPTION

The technical solution in implementations of the present disclosure will be described below clearly and completely with reference to accompanying drawings. Obviously, the described implementations are only some of the implementations rather than all implementations of the present disclosure. All other implementations obtained by one of ordinary skill in the art based on implementations provided in the present disclosure fall within the scope of the present disclosure.

In the description of the present disclosure, it is to be understood that terms “center”, “on”, “under”, “front”, “back”, “left”, “right”, “vertical”, “horizontal”, “top”, “bottom”, “inside”, “outside”, etc. refer to the orientation or position relationship based on what is shown in figures. The figures are provided only for the purpose of facilitating and simplifying the description the present disclosure rather than indicating or implying that the mentioned devices or elements must have certain orientation and/or must be constructed and operated in certain orientation. Therefore, the figures cannot be construed as limiting the present disclosure.

Unless otherwise stated in context, the term “include” will be interpreted in an open and containing sense, e.g., namely “contain but not limited to” throughout the description and claims. In the present description, terms such as “one implementation”, “some implementations”, “example implementation”, “illustratively” or “some examples” are intended to indicate certain features, structures, materials, or characteristics related to the implementation(s) or example(s) are included in at least one implementation or example of the present disclosure. The illustrative representation of the above terms does not necessarily refer to the same implementation or example. Furthermore, said certain features, structures, materials, or characteristics may be included in any one or more implementations or examples in any suitable manner.

As used herein, the terms “first”, “second”, etc. are only used for the purpose of description and should not be understood to indicate or imply relative importance or to designate the number of the referenced technical features implicitly. Therefore, a feature defined by “first” or “second” may include one or more instances of the feature explicitly or implicitly. In the description of implementations of the present disclosure, “a plurality of” means two or more unless otherwise specified.

“A and/or B” includes the following three combinations: only A, only B, and a combination of A and B.

The use of “adapted to” or “configured to” herein implies open and inclusive wording but not excluding apparatuses adapted to or configured to execute additional tasks or steps.

In addition, the use of “based on” implies open and inclusive wording, since a process, a step, a computation, or other acts “based on” one or more said conditions or values may be based on additional conditions or values other than said value in practice.

As used herein, “about” includes the stated value and the average value in the acceptable deviation range of a certain value. Said acceptable deviation range is determined by those of ordinary skill in the art considering the measurements under discussion and errors, e.g., namely limitations of the measurement system, related to measurements of a certain quantity.

In contents of the present disclosure, the meanings of “on”, “over” and “above” should be interpreted in the broadest manner such that “on” not only means “directly on” something but also includes the meaning of “on” something with an intermediate feature or a layer therebetween. Furthermore, “over” or “above” not only means the meaning of “over” or “above” something but can also include the meaning it is “above” or “over” something with no intermediate feature or layer therebetween (e.g., directly on something).

Example implementations are described herein with reference to sectional views and/or plan views as ideal illustrative drawings. In the drawings, thicknesses of layers and regions are enlarged for clarity. Therefore, it is possible to envision shape variations with respect to drawings due to manufacturing techniques and/or tolerances. Accordingly, example implementations should not be interpreted as limiting the shapes of regions shown herein, but including shape deviations caused by for example manufacturing. For example, an etched region shown as rectangular generally has curved features. Therefore, regions shown in drawings are illustrate in nature, and their shapes are not intended to show practical shapes of regions of an apparatus and not intended to limit the scope of example implementations.

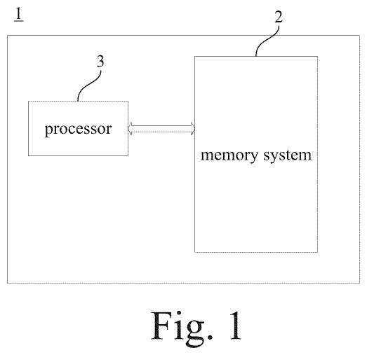

FIG. 1 is a block diagram of an electronic apparatus 1, according to some implementations of the present disclosure.

Referring to FIG. 1, the electronic apparatus 1 includes a memory system 2 and a processor 3. The processor 3 may be a central processing unit (CPU) and electrically connected with the memory system 2 to control operation of the memory system 2.

The electronic apparatus 1 may be any one of a mobile phone, a desktop computer, a tablet computer, a notebook computer, a server, an on-vehicle apparatus, a wearable apparatus such as a smart watch, a smart bracelet and a pair of smart glasses, a mobile power source, a game console, a digital multimedia player, etc.

The memory system 2 may be integrated into various memory apparatus such as being included in a Universal Flash Storage (UFS) package or an Embedded Multi Media Card (eMMC) package. The memory system 2 can be applied to different types of electronic products such as a mobile phone (e.g., a handset), a desktop computer, a tablet, a notebook computer, a server, an on-vehicle apparatus, a gaming console, a printer, a positioning apparatus, a wearable apparatus, a smart sensor, a mobile power source, a virtual reality (VR) apparatus, an argument reality (AR) apparatus, or any other suitable electronic apparatus having a storage therein.

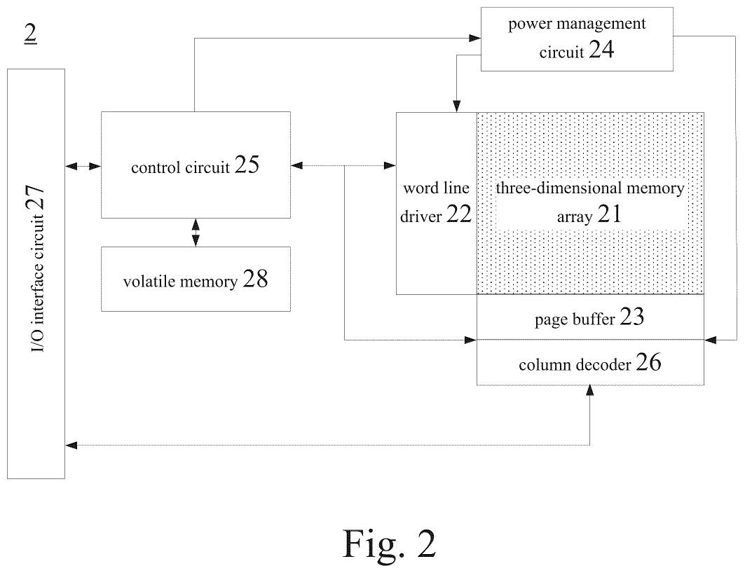

FIG. 2 is a block diagram of a memory system, according to some implementations of the present disclosure.

Referring to FIG. 2, the memory system 2 includes a three-dimensional memory array 21, a word line driver 22 (also known as a row decoder), a page buffer 23, a power management circuit (PMIC) 24, a control circuit 25, a column decoder 26 and an Input/Output (I/O) interface circuit 27.

Among others, the three-dimensional memory array 21 may include a plurality of memory blocks each of which may include a plurality of memory cells. The plurality of memory cells may be connected to the word line driver 22 via a string select line, a word line, and a ground select line, and may be connected to the page buffer 23 via a bit line.

In some implementations, the plurality of memory cells arranged along the same row may be connected to the same word line and the plurality of memory cells arranged along the same column may be connected to the same bit line.

The word line driver 22 may decode an input address to generate and transmit one or more driving signals such as word line voltage signals. The word line driver 22 may provide the word line voltage signals generated by the power management circuit 24 to one or more selected word lines of the plurality of word lines. Under the control of the control circuit 25, the unselected word lines of the plurality of word lines may receive another word line voltage signal.

The page buffer 23 may be connected to the three-dimensional memory array 21 via a bit line to read or sense data stored in the memory cells. Depending on the operation mode of the memory system 2, the page buffer 23 may be also configured to temporarily store data to be written or programmed into the memory cells. The page buffer 23 is also connected with the column decoder 26 that may selectively activate bit lines of the three-dimensional memory array 21.

The power management circuit 24 may use an external voltage to generate voltages required for interior operations such as programming voltage, reading voltage and erasing voltage. The voltages generated by the power management circuit 24 may be transmitted to the three-dimensional memory array 21 via the word line driver 22.

The control circuit 25 may control the overall operations of the word line driver 22 and the page buffer 23. The control circuit 25 may receive control signals and external voltages transmitted from outside entities. The control circuit 25 may operate depending on the received control signals, and may also control reading, writing and/or erasing operations in response to the control signals.

The I/O interface circuit 27 may receive written data in the programming operation and transmit the written data to the page buffer 23. The I/O interface circuit 27 may output the read data received from the page buffer 23 to an outside entity during the read operation. The I/O interface circuit 27 may also transmit the input address or instruction to the control circuit 25.

In some implementations, the memory system 2 further includes a volatile memory 28 that may be a dynamic random access memory (DRAM) or a register that may be used as buffer for the control circuit 25 for storing control programs. While the control circuit 25 is operating, high speed transmission between the control circuit 25 and the volatile memory 28 occurs therebetween to call the control programs quickly.

In some implementations, the memory system 2 includes a three-dimensional memory array 21, in which case, the memory system 2 may be a memory card.

The memory card includes any one of a PC card (PCMCIA), a Compact Flash (CF) card, a Smart Media (SM) card, a memory stick, a Multimedia Card (MMC), a Secure Digital Memory Card (SD), or a UFS, just to name a few.

In some other implementations, the memory system 2 includes a plurality of three-dimensional memory arrays 21, in which case, the memory system 2 may be a solid state disk (SSD).

In the memory system 2, the control circuit 25 is configured to operate in a low duty-cycle environment, e.g., such as SD cards, CF cards, Universal Serial Bus (USB) flash drives, or other media used in an electronic apparatus, e.g., such as personal calculators, digital cameras, and mobile phones.

Alternatively, the control circuit 25 is configured to operate in high duty cycle environment SSDs or eMMCs that are used as data stores and enterprise memory arrays of the mobile apparatus, e.g., such as smart phones, tablet computers, and notebook computers, just to name a few.

In some implementations, the memory system further includes a circuit board and a chip-package structure disposed on the circuit board that includes a plurality of chips. The plurality of chips may be chips such as a three-dimensional memory array, a power management circuit, a control circuit, and a memory and are tiled along the surface of the circuit board, resulting in a large size of the memory system.

In the above-described plurality of chips, with the size of three-dimensional memory array scaling down, sizes of other chips cannot be reduced as being constrained by the process precision, which cannot match the size reduction of the memory system and limit the overall size reduction of the memory system. Thus, there exists an unmet need for a technique to further reduce of electronic devices.

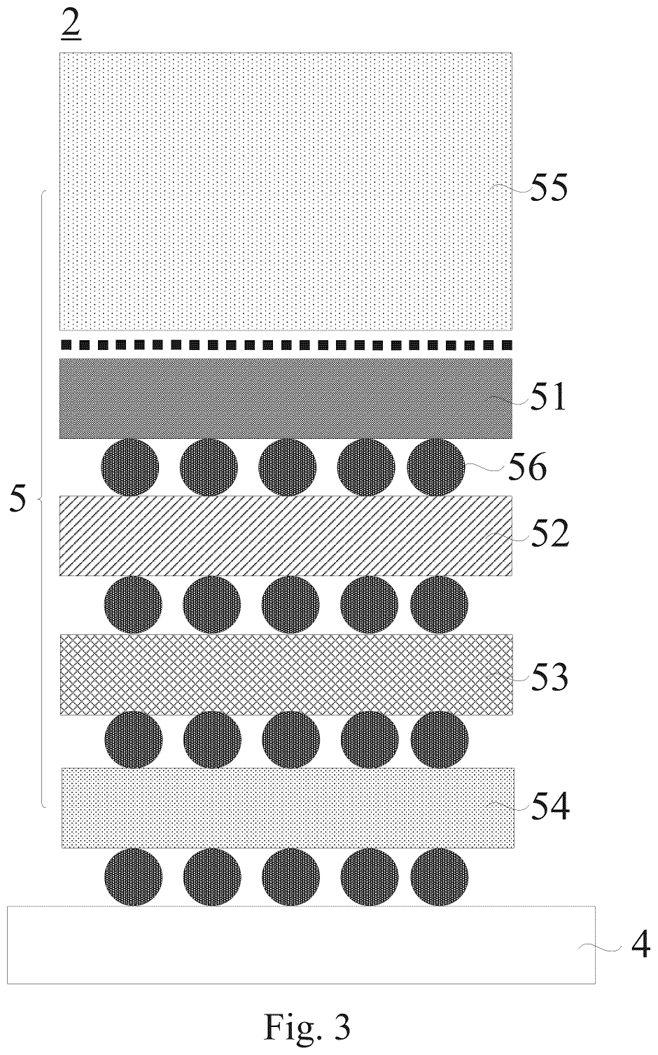

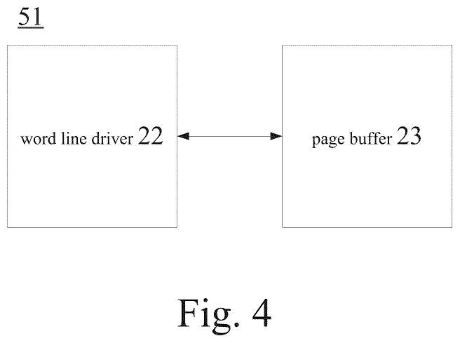

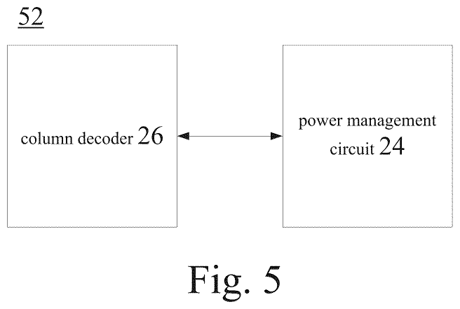

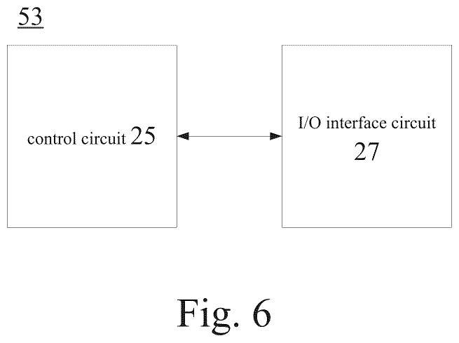

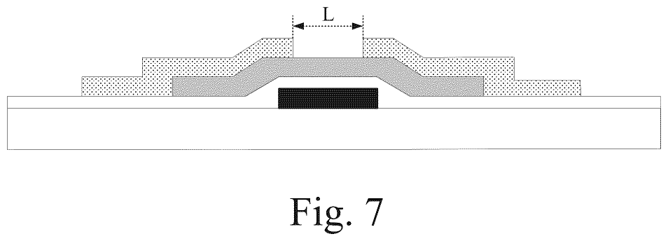

In order to address the above-described problem, some implementations of the present disclosure provide a memory system. FIG. 3 is a structure diagram of a memory system, according to some implementations of the present disclosure. FIG. 4 is a block diagram of a first chip, according to some implementations of the present disclosure. FIG. 5 is a block diagram of a second chip, according to some implementations of the present disclosure. FIG. 6 is a block diagram of a third chip, according to some implementations of the present disclosure. FIG. 7 is a structure diagram of a transistor in the chip, according to some implementations of the present disclosure.

Referring to FIG. 3, the memory system 2 includes a circuit board 4 and a chip-package structure 5 disposed on the circuit board 4. The chip-package structure 5 may include, e.g., a first chip 51, a second chip 52, and a third chip 53 stacked one on another to form a stacked structure.

Referring to FIG. 4, the first chip 51 includes at least a peripheral circuit that may include, e.g., the aforementioned word line driver 22 and the page buffer 23. The word line driver 22 and the page buffer 23 may include a first transistor.

In the memory system 2, the word line driver 22 and the page buffer 23 may each include a first transistor, and both the word line driver 22 and the page buffer 23 may include the same type of transistor. Also, the word line driver 22 and the page buffer 23 may have roughly same operating voltage ranges of for example 2.5V-30V. Therefore, it is possible to fabricate the word line driver 22 and the page buffer 23 on the first chip 51 with the same process, which realizes modularization of circuits, simplifies the manufacturing process of the word line driver 22 and the page buffer 23, and reduces processing costs.

In some implementations, the first transistor may be a CMOS transistor and may be fabricated with a metal-oxide-semiconductor (MOS) process to fabricate circuits on the first chip 51.

Referring to FIG. 5, the second chip 52 may include at least the aforementioned column decoder 26, which includes the second transistor therein. The second chip 52 may further include, e.g., the aforementioned power management circuit 24, which also includes the second transistor.

In the memory system 2, the column decoder 26 and the power management circuit 24 each includes a second transistor, and both the column decoder 26 and the power management circuit 24 may include the same type of transistor. Also, the column decoder 26 and the power management circuit 24 have roughly the same operating voltage ranges, e.g., 3.3V-30V. Therefore, it is possible to fabricate the column decoder 26 and the power management circuit 24 on the second chip 52 with the same process, which realizes modularization of circuits, simplifies the manufacturing process of the column decoder 26 and the power management circuit 24, and reduces processing costs.

In some implementations, the second transistor is a CMOS transistor, and the column decoder 26 and the power management circuit 24 further includes bipolar transistors and DMOS transistors. The bipolar transistors, the CMOS transistors and the DMOS transistors may be fabricated with a Bipolar-CMOS-DMOS (BCD) process to fabricate circuits on the second chip 52.

Referring to FIG. 6, the third chip 53 may include at least the aforementioned control circuit 25, which includes the third transistor therein. The third chip 53 may further include, e.g., the aforementioned I/O interface circuit 27, which also includes the third transistor therein.

In the memory system 2, the control circuit 25 and the I/O interface circuit 27 each include a third transistor. Both the control circuit 25 and the I/O interface circuit 27 may include the same type of transistor. Also, the control circuit 25 and the I/O interface circuit 27 have roughly same operating voltages, e.g., about 1.1V. Therefore, it is possible to fabricate the control circuit 25 and I/O interface circuit 27 on the third chip 53 using the same process, which realizes modularization of circuits, simplifies the manufacturing process of the control circuit 25 and the I/O interface circuit 27, and reduces processing costs.

In some implementations, the third transistor may be a CMOS transistor, which is fabricated with a MOS process to fabricate circuits on the third chip 53.

Referring to FIG. 7, a channel length L of a transistor is an important parameter that influences transistor performance. In the fabrication process of the first chip 51, the second chip 52, and the third chip 53, by adjusting process parameters to enable different chips to have different process parameters such that the channel length of the first transistor (e.g., a first channel length), the channel length of the second transistor (e.g., a second channel length), and the channel length of the third transistor (e.g., a third channel length) are different. This enables circuits in different chips to operating using different operating voltages.

In some implementations, the channel length (e.g., the first channel length) of the first transistor is in a range of 40 nm-180 nm. For example, the channel length of the first transistor may be 40 nm, 75 nm, 110 nm, 145 nm, or 180 nm. The channel length (e.g., the second channel length) of the second transistor is in a range of 130nm or more. For example, the channel length of the second transistor may be 130 nm, 140 nm, 150 nm, 160 nm, or 170 nm. The channel length (e.g., the third channel length) of the third transistor is in a range of 14 nm-40 nm. For example, the channel length of the third transistor may be 14 nm, 20 nm, 27 nm, 28 nm, or 40 nm.

In the memory system 2, the chip-package structure 5 includes a first chip 51, a second chip 52, and a third chip 53 stacked to form a stacked structure. The first chip 51 includes at least a peripheral circuit including the first transistor. In other words, the peripheral circuit is a circuit that applies the first transistor integrated in the first chip 51. The second chip 52 includes at least the column decoder 26 including the second transistor. In other words, the column decoder 26 is a circuit that applies the second transistor integrated in the second chip 52. The third chip 53 includes at least the control circuit 25 including the third transistor. In other words, the control circuit 25 is a circuit that applies the third transistor integrated in the third chip 53.

The plurality of circuits in the same chip apply the same transistors, so the plurality of circuits have the same fabrication process parameters. Therefore, it is possible to form the plurality of circuits in the same chip with the same process. Moreover, the process parameters for fabricating different chips are different such that the channel length of the first transistor, the channel length of the second transistor, and the channel length of the third transistor are different from each other. As such, circuits in different chips may use different operating voltages.

As compared to the plurality of chips tiled along the horizontal direction, by stacking the first chip 51, the second chip 52, and the third chip 53 with different process parameters, it is possible to reduce the size of the chip-package structure 5 in the horizontal direction, e.g., by more than 50%. This reduces the size of the memory system 2 that applies the chip-package structure 5.

In some implementations, referring to FIG. 3, the chip-package structure 5 may further include a fourth chip 54 including the aforementioned volatile memory 28.

The fourth chip 54 may be stacked with the first chip 51, the second chip 52, and the third chip 53 to facilitate connecting the fourth chip 54 directly with the third chip 53. This enables high speed signal transmission between the volatile memory 28 in the fourth chip 54 and the control circuit 25 in the third chip 53. Using this example configuration, the size of the chip-package structure 5 in the horizontal direction may be reduced, thereby reducing the overall size of the memory system 2.

In some implementations, as shown in FIG. 3, in case that the first chip 51, the second chip 52, and the third chip 53 are stacked sequentially, the fourth chip 54 may be disposed on a side of the third chip 53 that is away from the first chip 51.

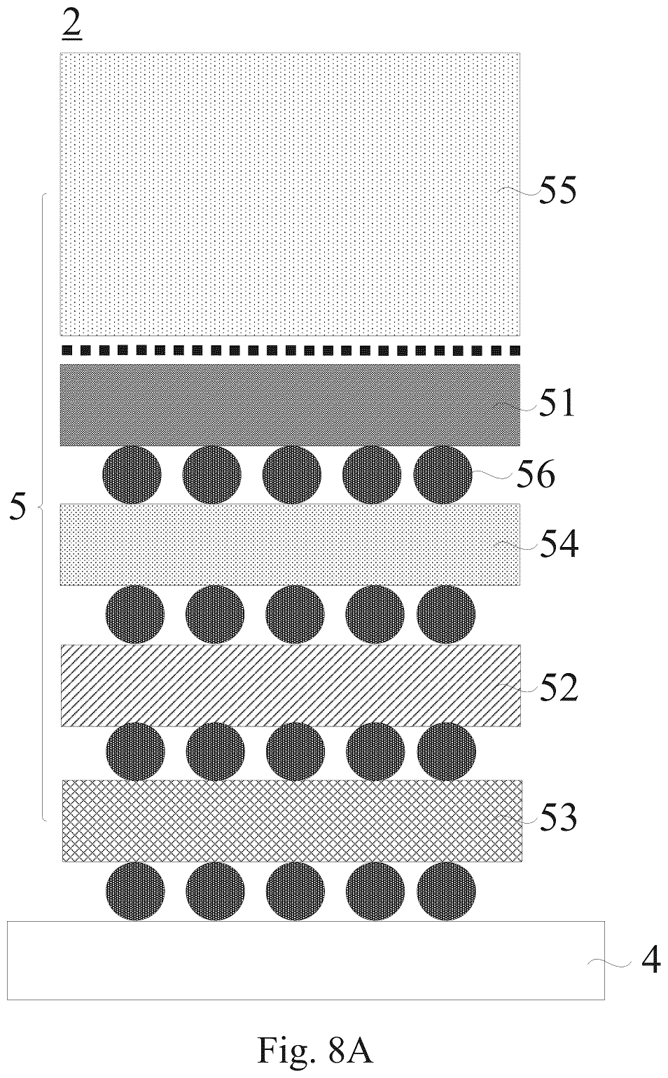

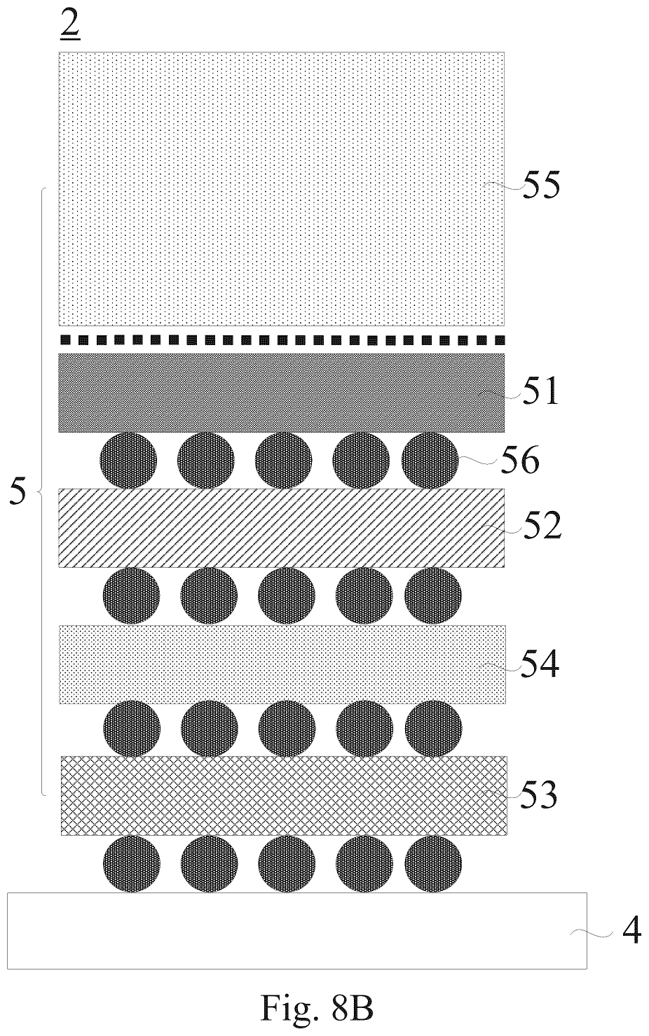

FIGS. 8A and 8B are structure diagrams of some other memory systems, according to some implementations of the present disclosure.

In the case that the first chip 51, the second chip 52 and the third chip 53 are stacked sequentially, as shown in FIG. 8A, the fourth chip 54 may also be disposed between the first chip 51 and the second chip 52. Alternatively, as shown in FIG. 8B, the fourth chip 54 may also be disposed between the second chip 52 and the third chip 53.

In addition, the first chip 51, the second chip 52, and the third chip 53 may also not be stacked in turn, and the stacking order of these three chips may be adjusted according to different use-case scenarios.

In some implementations, referring to FIGS. 8A and 8B, the chip-package structure 5 may further include a fifth chip 55, which is part of the three-dimensional memory array 21. The fifth chip 55 may be stacked with the first chip 51, the second chip 52, and the third chip 53. By stacking the fifth chip 55 horizontally with the other chips, the size of the chip-package structure 5 may be reduced in the horizontal direction, thereby reducing the overall size of the memory system 2.

In some implementations, a memory cell of the three-dimensional memory array 21 may include a plurality of transistors for storage. For example, each memory cell includes at least five-hundred transistors.

As described above, the first chip 51 may include a peripheral circuit. The peripheral circuit may include, e.g., the word line driver 22 and the page buffer 23 that each perform high speed signal transmission with the three-dimensional memory array 21. As such, the fifth chip 55 may be disposed adjacent to the first chip 51 to facilitate interconnection therebetween, thereby ensuring signal-transmission efficiency therebetween.

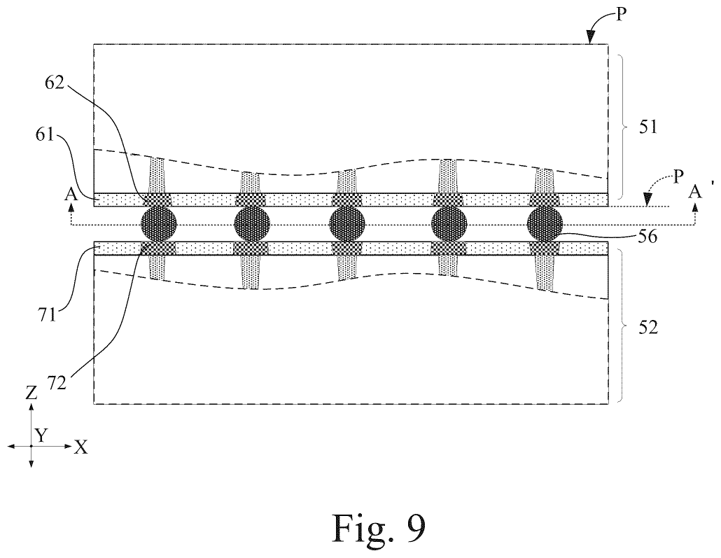

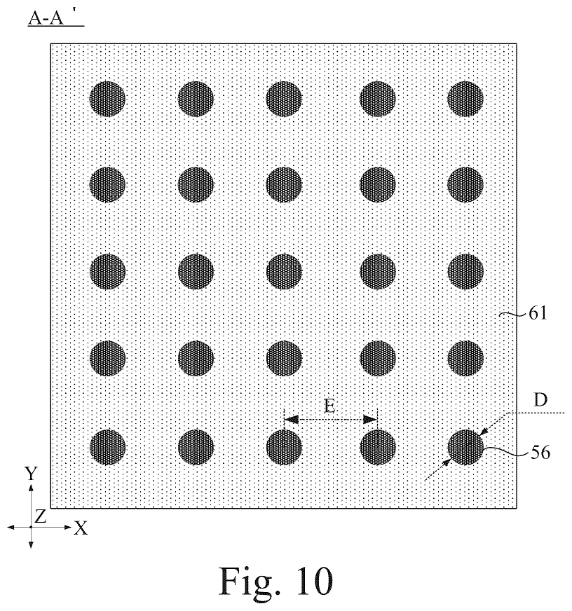

FIG. 9 is a diagram of a connection between chips, according to some implementations of the present disclosure. FIG. 10 is a sectional view of the structure in FIG. 9 along the section line A-A′, according to some implementations of the present disclosure.

Referring to FIG. 9, in the stacked structure, considering the first chip 51 adjacent to the second chip 52 as an example, the first chip 51 and the second chip 52 may be interconnected via a connection structure 56.

It is appreciated that in the stacked plurality of chips, any two adjacent chips may be interconnected via the connection structure 56, which is not limited in implementations of the present disclosure.

In some implementations, the first chip 51 may include a first dielectric layer 61 on its surface and a first conductive pattern 62 penetrating the first dielectric layer 61. The second chip 52 may include a second dielectric layer 71 on its surface and a second conductive pattern 72 penetrating the second dielectric layer 71. The first conductive pattern 62 of the first chip 51 may be electrically connected with the second conductive pattern 72 of the second chip 52 through the connection structures 56. Interconnecting chips via connection structures 56 may be achieved with low-process difficulty and low-process cost.

Furthermore, in the stacked plurality of chips, a chip connected directly with the circuit board 4 may also be interconnected with the connection structure 56. For example, the connection structure 56 may include any one of a solder ball, a solder bump, or a copper (Cu) pillar.

In some implementations, referring to FIGS. 9 and 10, the first chip 51 may include a surface P close to or away from a side of the second chip 52, and the connection structure 56 may have a circular orthogonal projection on the surface P. The circular orthogonal projection may have a diameter D in the range of 1 μm-10 μm. For example, the diameter of the circular orthogonal projection may be 1 μm, 3 μm, 5.5 μm, 8 μm, or 10 μm, just to name a few. As compared to the size of the connection structure in the current products in volume production, the diameter D of the circular orthogonal projection of the connection structure 56 is on the order of microns. In this way, the area occupied by the connection structure 56 may be reduced, which facilitates miniaturization of the device.

In case that the connection structure 56 is a solder bump, since the diameter of the circular orthogonal projection of the connection structure 56 is on the order of microns, the connection structure 56 is also referred to as a micro bump.

In some implementations, referring to FIGS. 9 and 10, in the direction parallel to the surface P (e.g., along the plane X-Y), a plurality of connection structures 56 may be arranged in an array. The spacing E between two adjacent connection structures 56 may be in the range of 1 μm-10 μm. For example, the spacing E between two adjacent connection structures 56 may be 1 μm, 4 μm, 5.5 μm, 7 μm, or 10 μm, just to name a few.

As compared to the spacing of the connection structures in other volume-production products, the size of the connection structure 56 in implementations of the present disclosure is small, which facilitates reducing the spacing E between connection structures 56 and facilitates miniaturization of the device.

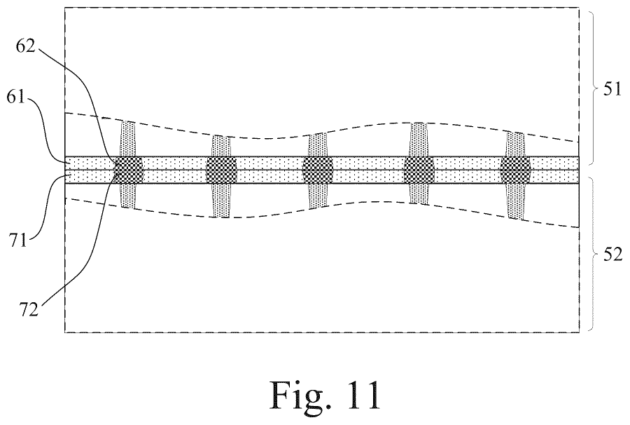

FIG. 11 is a diagram of a connection between chips, according to some implementations of the present disclosure.

Referring to FIG. 11, considering the first chip 51 adjacent to the second chip 52 as an example, the two adjacent chips may be interconnected via hybrid bonding.

It is appreciated that in the stacked plurality of chips, any two adjacent chips may be interconnected via hybrid bonding, which is not limited in implementations of the present disclosure.

In some implementations, the first dielectric layer 61 of the first chip 51 may be bonded with the second dielectric layer 71 of the second chip 52, and the first conductive pattern 62 of the first chip 51 may be bonded with the second conductive pattern 72 of the second chip 52. The conductive patterns of the two chips are made to contact by hybrid bonding, which facilitates high speed signal transmission among chips.

In the memory system 2, the word line driver 22 and the page buffer 23 may each be connected with the three-dimensional memory array 21 to facilitate the high speed signal transmission. Therefore, the fifth chip 55 and the first chip 51 are connected via hybrid bonding, which facilitates the high speed signal transmission between the word line driver 22 and the page buffer 23 in the first chip 51 and the three-dimensional memory array 21 in the fifth chip 55.

In the memory system 2, high-speed signal-transmission between the volatile memory 28 and the control circuit 25 is achieved. To that end, the fourth chip 54 and the third chip 53 may be connected via hybrid bonding, which facilitates the high-speed signal-transmission between the volatile memory 28 in the fourth chip 54 and the control circuit 25 in the third chip 53.

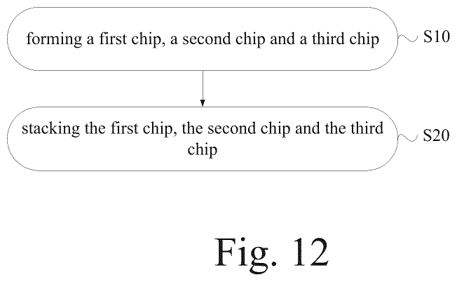

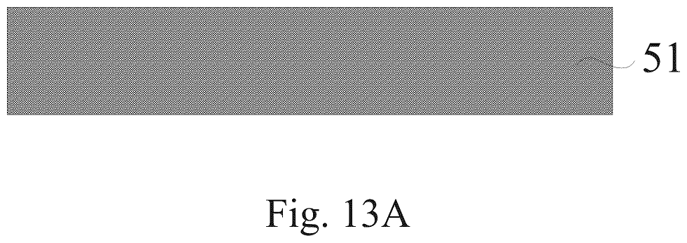

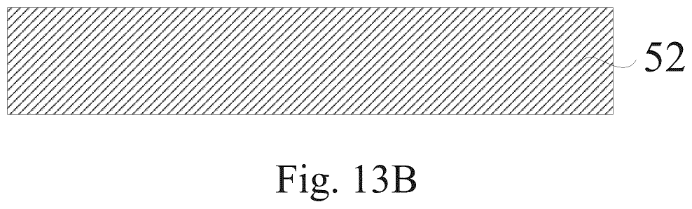

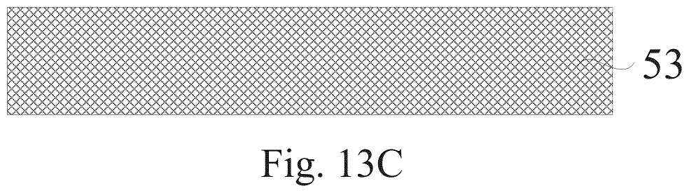

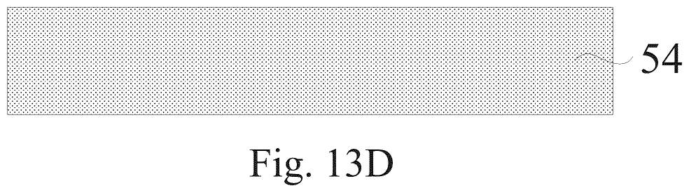

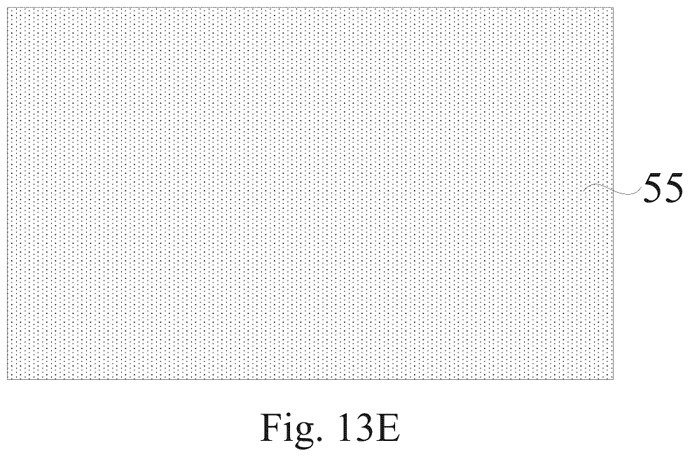

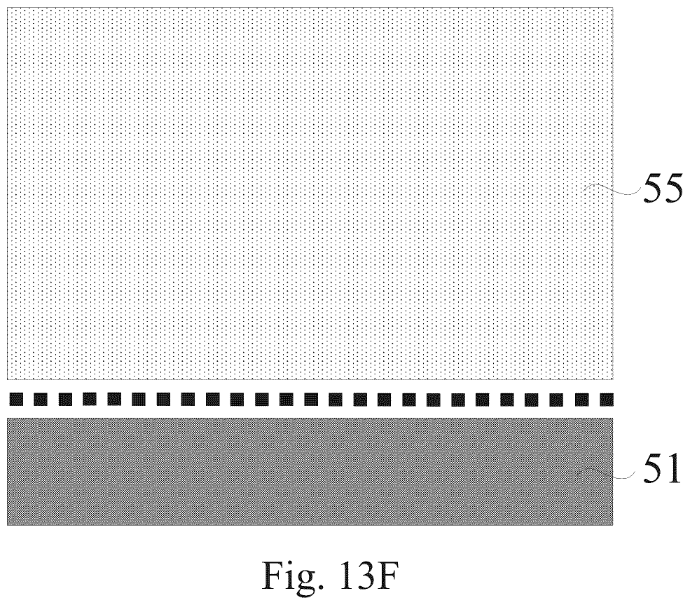

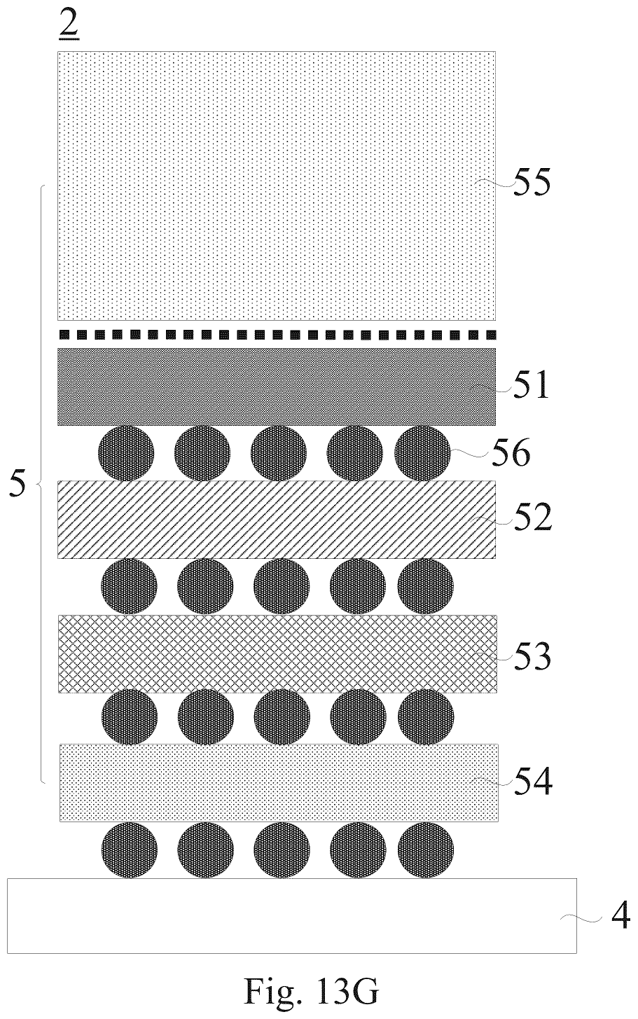

Some implementations of the present disclosure further provide a method of fabricating the chip-package structure shown in FIG. 3. For example, FIG. 12 is a flow diagram of a method of fabricating a chip-package structure, according to some implementations of the present disclosure. FIGS. 13A-13G are flow diagrams for fabricating a chip-package structure, according to some implementations of the present disclosure.

Referring to FIG. 12, method of fabricating the chip-package structure may include operations S10-S20.

At operation S10, referring to FIGS. 13A-13C, the method may include forming a first chip 51, a second chip 52 and a third chip 53. The first chip 51 may include at least a peripheral circuit including a first transistor. The second chip 52 may include at least a column decoder 26 including a second transistor. The third chip 53 may include at least a control circuit 25 including a third transistor.

In some implementations, each of the first chip 51, the second chip 52, and the third chip 53 includes a plurality of circuits. For example, the peripheral circuit of the first chip 51 may include a word line driver 22 and a page buffer 23. The second chip 52 may include a column decoder 26 and a power management circuit 24. The third chip 53 may include a control circuit 25 and an I/O interface circuit 27.

In this way, a plurality of circuits may be formed on the same chip with the same process, which simplifies the fabrication process of the chip and has a low process cost.

In the fabrication process of the first chip 51, the second chip 52, and the third chip 53, by adjusting process parameters to enable different chips have different process parameters such that a channel length of the first transistor, a channel length of the second transistor, and a channel length of the third transistor in the chips are different from each other, the circuits in these different chips may use different operating voltages.

Referring to FIGS. 13D and 13E, the method of fabricating the chip-package structure may further include forming a fourth chip 54 and a fifth chip 55. The fourth chip 54 may include a volatile memory 28, and the fifth chip 55 may include a three-dimensional memory array 21.

Referring to FIG. 13F, to ensure a high speed signal transmission between the fifth chip 55 and the first chip 51, before stacking the first chip 51, the second chip 52 and the third chip 53, a surface of the fifth chip 55 may be bonded with a surface of the first chip 51 to form a bonded structure and then the bonded structure is connected with the second chip 52.

At operation S20, referring to FIG. 13G, the method may include stacking the first chip 51, the second chip 52, and the third chip 53.

In some implementations, the fourth chip 54 may be connected on the circuit board 4 first. Then, the third chip 53 may be connected on the fourth chip 54. Next, the second chip 52 may be connected on the third chip 53. Finally, the bonded structure of the fifth chip 55 and the first chip 51 may be connected on the second chip 52 (e.g., the first chip 51 and the second chip 52 are connected directly).

In some implementations, surfaces of two adjacent chips may be connected using a bonding process such as a hybrid bonding process. Alternatively, two adjacent chips may be connected through a connection structure 56.

In the fabrication method provided in the above-described implementations of the present disclosure, in the process of fabricating the plurality of circuits of the memory system 2, the same process conditions (e.g., such as process parameters) are classified and circuits of the same class of process (with the same process parameters) may be fabricated on the same chip.

For example, the peripheral circuit may include a word line driver 22 and a page buffer 23, both of which include the same type of transistors (first transistors); therefore, the word line driver 22 and the page buffer 23 may be fabricated on the first chip 51. The column decoder 26 and the power management circuit 24 may include the same type of transistors (second transistors); therefore, the column decoder 26 and the power management circuit 24 may be fabricated on the second chip 52. The control circuit 25 and the I/O interface circuit 27 include the same type of transistors (third transistors); therefore, the control circuit 25 and the I/O interface circuit 27 may be fabricated on the third chip 53, which simplifies the fabrication process and has a low process cost.

As compared to the plurality of chips being tiled along the horizontal direction, by stacking the first chip 51, the second chip 52 and the third chip 53, it is possible to reduce the size of the chip-package structure 5 in the horizontal direction, thereby reducing the size of the memory system 2 that applies the chip-package structure 5.

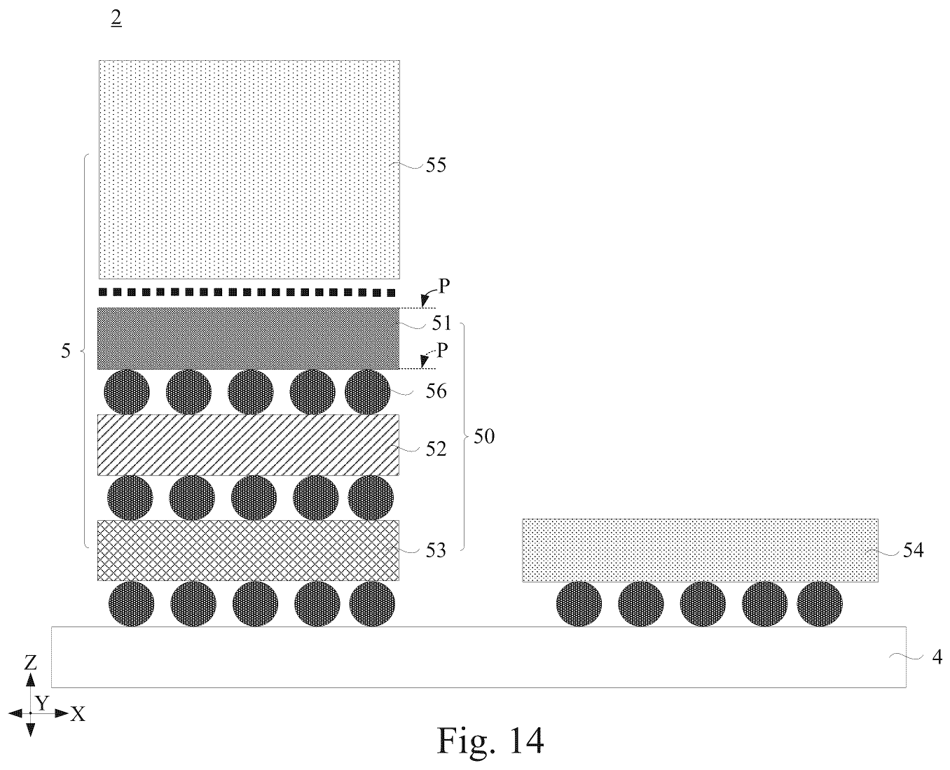

FIG. 14 is a structure diagram of yet another memory system, according to some implementations of the present disclosure.

Referring to FIG. 14, the chip-package structure 5 may further include a fourth chip 54. In this example, the first chip 51, the second chip 52, and the third chip 53 form a stack structure 50, and the fourth chip 54 is arranged side-by-side with the stack structure 50 in a first direction X that is parallel to the surface P of the first chip 51.

In some implementations, the fourth chip 54 may be disposed side-by-side with the stack structure 50 on the circuit board 4, and the fourth chip 54 is tiled with the stack structure 50 along the surface of the circuit board 4. The fourth chip 54 and the stack structure 50 may each be connected with the circuit board 4 via a connection structure 56.

As compared to the three-dimensional memory array, the power management circuit, the control circuit and the memory circuit being tiled on the surface of the circuit board, in the above-described implementations of the present disclosure, the fourth chip 54 and the stack structure 50 are disposed side-by-side such that the chip-package structure 5 has an area of only two chips. The chip-package structure 5 has a small are along the X-Y plane, thereby reducing the occupied area of the chip-package structure 5 on the circuit board 4, which facilitates reducing the area of the memory system 2 and realizes miniaturization of the device.

The fourth chip 54 and the stack structure 50 are connected with the circuit board 4 using a simple process. The fourth chip 54 is electrically connected with the third chip 53 via the circuit board 4 to facilitate electrical connection between the volatile memory 28 in the fourth chip 54 and the control circuit 25 in the third chip 53.

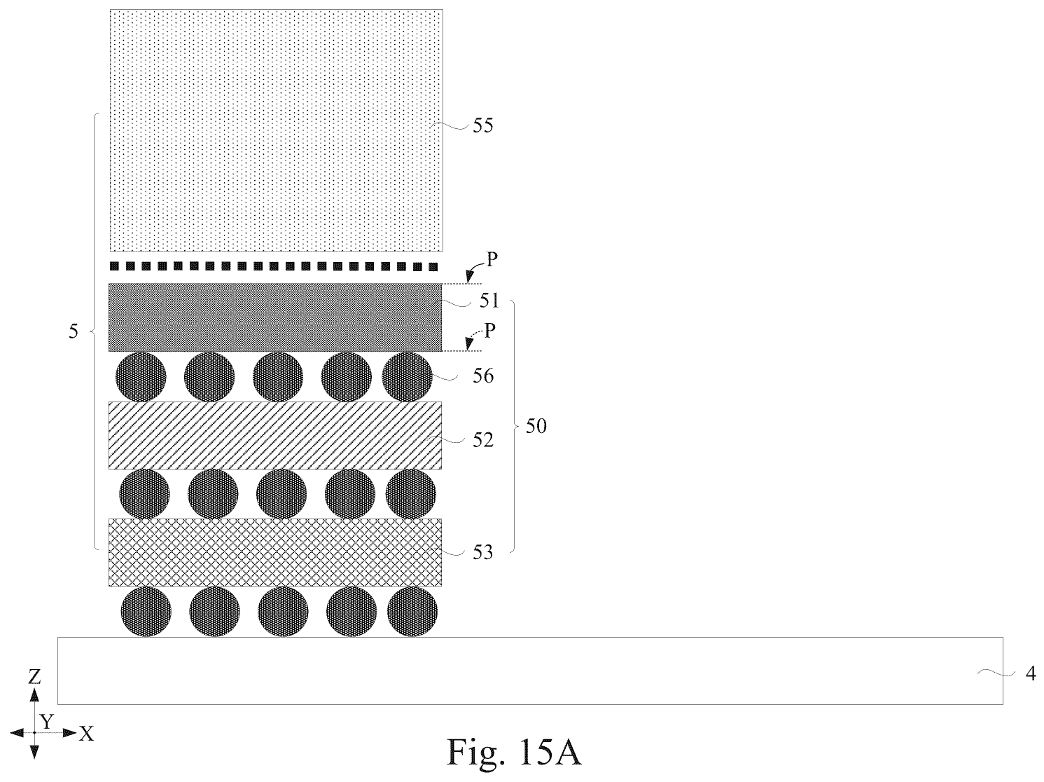

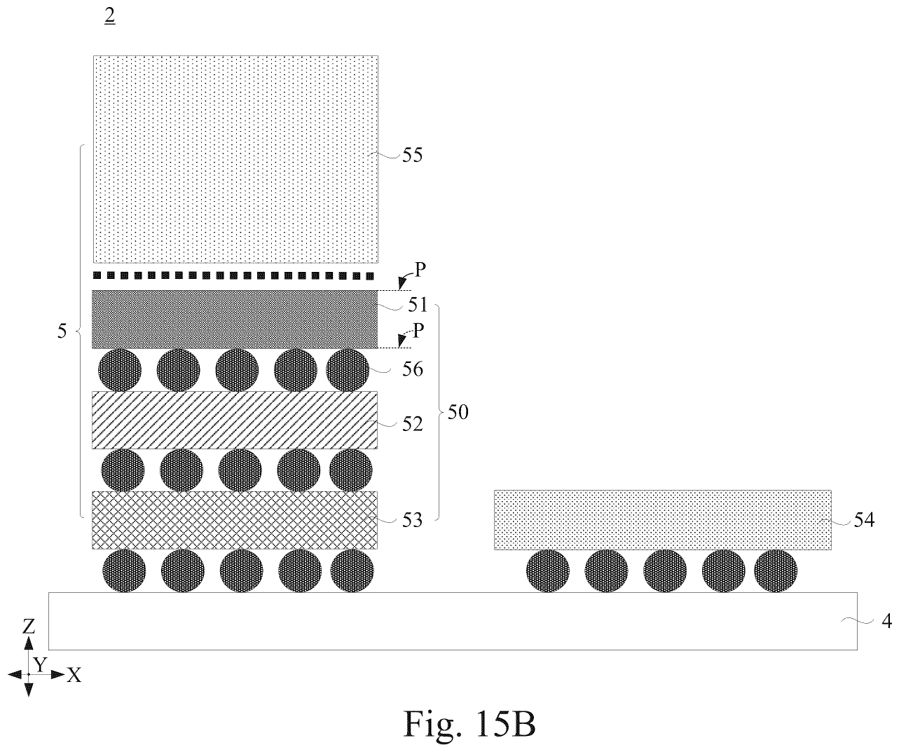

Some implementations of the present disclosure further provide a method of fabricating the chip-package structure, as shown in FIG. 14. FIGS. 15A-15B are flow diagrams of a method of fabricating a chip-package structure, according to some implementations of the present disclosure.

Similar to the aforementioned fabrication method, the first chip 51, the second chip 52, the third chip 53, the fourth chip 54, and the fifth chip 55 are formed first; and then, a surface of the fifth chip 55 is bonded with a surface of the first chip 51 to form a bonded structure.

Referring to FIG. 15A, the first chip 51, the second chip 52, and the third chip 53 are stacked.

In some implementations, the third chip 53 may be connected on the circuit board 4 first; then, the second chip 52 may be connected on the third chip 53; and finally, the bonded structure of the fifth chip 55 and the first chip 51 may be connected on the second chip 52 (e.g., the first chip 51 and the second chip 52 are connected directly).

Referring to FIG. 15B, connecting the fourth chip 54 with the circuit board 4 may be performed before or after stacking the first chip 51, the second chip 52, and the third chip 53, without limitation.

In the fabrication method provided in the above-described implementations of the present disclosure, instead of stacking the fourth chip 54 with the first chip 51, the second chip 52 and the third chip 53, the fourth chip 54 may be connected with the circuit board 4 separately through a simple connection process, which facilitates reducing the process cost.

The above description provides some example implementations of the present disclosure. The scope of the present disclosure is not limited thereto. Variations and substitutions that easily occur to any one skilled in the art in the technical scope disclosed by the present disclosure should be encompassed in the scope of the present disclosure. Therefore, the scope of the present disclosure should be determined by the scope of the claims.

What is claimed is:

1. A chip-package structure, comprising:
a first chip comprising at least a peripheral circuit comprising a first transistor;
a second chip comprising at least a column decoder comprising a second transistor; and
a third chip comprising at least a control circuit comprising a third transistor,
wherein the first chip, the second chip, and the third chip form a stacked structure, and
wherein a first channel length of the first transistor, a second channel length of the second transistor, and a third channel length of the third transistor are different.

2. The chip-package structure of claim 1, wherein:
the peripheral circuit comprises at least a word line driver and a page buffer each comprising the first transistor,
the second chip further comprises a power management circuit comprising the second transistor, and
the third chip further comprises an input/output (I/O) interface circuit comprising the third transistor.

3. The chip-package structure of claim 1, wherein:
the first transistor, the second transistor and the third transistor are each a complementary metal-oxide-semiconductor (CMOS) transistor,
the column decoder further comprises a fourth transistor and a fifth transistor, and
the fourth transistor is a bipolar transistor and the fifth transistor is a double-diffused metal-oxide-semiconductor (DMOS) transistor.

4. The chip-package structure of claim 3, wherein the second chip further comprises a power management circuit comprising the fourth transistor and the fifth transistor.

5. The chip-package structure of claim 1, further comprising:
a fourth chip comprising a volatile memory,
wherein the fourth chip is stacked with the first chip, the second chip, and the third chip.

6. The chip-package structure of claim 1, further comprising:
a fourth chip comprising a volatile memory,
wherein the first chip, the second chip, and the third chip are stacked in a first direction, and
wherein the fourth chip is placed adjacent to the stack structure in a second direction perpendicular to the first direction.

7. The chip-package structure of claim 1, wherein:
one chip of two adjacent chips in the stacked structure comprises a first dielectric layer on one of its surfaces and a first conductive pattern penetrating the first dielectric layer,
another chip of the two adjacent chips in the stacked structure comprises a second dielectric layer on one of its surfaces and a second conductive pattern penetrating the second dielectric layer,
the first conductive pattern is bonded with the second conductive pattern, and
the first dielectric layer is bonded with the second dielectric layer.

8. The chip-package structure of claim 1, wherein:
one chip of two adjacent chips in the stack structure comprises a first dielectric layer on one of its surfaces and a first conductive pattern penetrating the first dielectric layer,
another chip of the two adjacent chips in the stack structure comprises a second dielectric layer on one of its surfaces and a second conductive pattern penetrating the second dielectric layer, and
the chip-package structure further comprises a connection structure through which the first conductive pattern is electrically connected with the second conductive pattern.

9. The chip-package structure of claim 8, wherein the connection structure comprises any one of a solder ball, a solder bump, or a copper (Cu) pillar.

10. The chip-package structure of claim 8, wherein:
the first chip comprises a first surface close to or away from a side of the second chip,
the connection structure has a circular orthogonal projection on the first surface, and
a diameter of the circular orthogonal projection is in a range of 1 μm-10 μm.

11. The chip-package structure of claim 8, wherein:
the first chip comprises a first surface close to or away from a side of the second chip,
the connection structure comprises a plurality of the connection structures arranged in an array in a direction parallel to the first surface, and
a spacing between two adjacent connection structures is in a range of 1 um-10 um.

12. The chip-package structure of claim 7, further comprising:
a fifth chip comprising a three-dimensional memory array,
wherein the fifth chip is stacked with the first chip, the second chip and the third chip, and
wherein the fifth chip is disposed adjacent to the first chip.

13. The chip-package structure of claim 1, wherein:
the first channel length of the first transistor is in a range of 40 nm-180 nm,
the second channel length of the second transistor is greater than or equal to 130 nm, and
the third channel length of the third transistor is in a range of 14 nm-40 nm.

14. A method of fabricating a chip-package structure comprising:
forming a first chip comprising at least a peripheral circuit comprising a first transistor;
forming a second chip comprising at least a column decoder comprising a second transistor;
forming a third chip comprising at least a control circuit comprising a third transistor; and
stacking the first chip, the second chip, and the third chip to form a stack structure,
wherein a first channel length of the first transistor, a second channel length of the second transistor, and a third channel length of the third transistor are different.

15. The method of claim 14, wherein:
the first chip, the second chip, and the third chip each comprise a plurality of circuits, and the method further comprises:
forming the plurality of circuits on a same chip using the same process, or
forming the plurality of circuits on different chips with different process parameters.

16. The method of claim 14, further comprising:
forming a fourth chip comprising a volatile memory; and
stacking the fourth chip with the first chip, the second chip, and the third chip.

17. The method of claim 14, wherein surfaces of two adjacent chips in the stack structure are connected using a bonding process.

18. The method of claim 14, wherein two adjacent chips of the stack structure are connected using a connection structure.

19. The method of claim 16, wherein:
before the stacking the first chip, the second chip, and the third chip to form the stack structure, the method further comprises:
connecting a surface of a fifth chip and a surface of the first chip using a bonding process to form a bonded structure, the first chip comprising a three-dimensional memory array, and
the stacking the first chip, the second chip, and the third chip to form the stack structure comprises:
stacking the bonded structure, the second chip, and the third chip.

20. A memory system comprising:
a chip-package structure comprising:
a first chip comprising at least a peripheral circuit comprising a first transistor;
a second chip comprising at least a column decoder comprising a second transistor; and
a third chip comprising at least a control circuit comprising a third transistor,
wherein the first chip, the second chip, and the third chip form a stacked structure, and
wherein a first channel length of the first transistor, a second channel length of the second transistor, and a third channel length of the third transistor are different; and
a circuit board electrically connected with the chip-package structure.
